(19) United States
(12) Patent Application Publication
(10) Pub. No.: US 2011/0187004 A1
(43) Pub. Date: Aug. 4, 2011

(54) SEMICONDUCTOR DEVICES INCLUDING AN INTERCONNECTION PATTERN AND METHODS OF FABRICATING THE SAME

(76) Inventor: Sang-Hoon Park, Hwaseong-si (KR)

(21) Appl. No.: 12/980,729

(22) Filed: Dec. 29, 2010

(30) Foreign Application Priority Data
Feb. 1, 2010 (KR) 10-2010-0009254

(51) Int. Cl. H01L 23/48

(52) U.S. Cl. 257/774; 257/E23.011

(57) ABSTRACT

A semiconductor device includes a first insulating layer having a plurality of via plugs therein, a second insulating layer on the first insulating layer, and a conducting interconnection pattern disposed in the second insulating layer and having at least one interconnection landing arranged over and electrically connected to the via plugs.

A method of fabricating a semiconductor device includes forming a lower conducting layer, forming a first insulating layer on the lower conducting layer, forming a via plug vertically penetrating the first insulating layer and connected to the lower conducting layer, forming a second insulating layer on the first insulating layer and the via plugs, forming a first recess in the second insulating layer, the first recess having a bottom surface lower than a top surface of the second insulating layer, forming a trench in the second insulating layer and simultaneously further recessing the first recess to form a second recess, and forming a conducting material in the second recess and the trench.

### CROSS-REFERENCE TO RELATED APPLICATION

This application claims priority under 35 U.S.C. §119 to Korean Patent Application No. 10-2010-0009254 filed on Feb. 1, 2010, the disclosure of which is hereby incorporated by reference in their entirety.

### BACKGROUND

1. Field

Embodiments of the inventive concept relate to semiconductor devices including an interconnection pattern having an interconnection landing, and methods of fabricating semiconductor devices including an interconnection pattern having an interconnection landing.

2. Description of Related Art

Highly integrated semiconductor devices and multifunctional embedded semiconductor devices are being developed as advanced semiconductor devices. With the scale down of such advanced semiconductor devices, the device tend to have a high aspect ratio contact hole structure. The via plug with high aspect ratio can lead to a manufacturing yield drop and electrical failure.

### SUMMARY

It is therefore an aspect of the embodiments of the inventive concept to provide a semiconductor device having an interconnection pattern structure for reducing the aspect ratio of a via plug.

It is a further aspect of the embodiments of the inventive concept to provide methods of fabricating semiconductor devices having an interconnection pattern structure for reducing the aspect ratio of a via plug.

It is a further aspect of the embodiments of the inventive concept to provide an electronic system including a semiconductor device having an interconnection pattern structure for reducing the aspect ratio of a via plug.

The embodiment of the inventive concept includes a semiconductor device including a first insulating layer having a plurality of via plugs therein, a second insulating layer on the first insulating layer, and a conducting interconnection pattern disposed in the second insulating layer and having at least one interconnection landings arranged over and electrically connected to the via plugs.

In a preferred embodiment, a portion of the conducting interconnection pattern other than the interconnection landings has a bottom surface higher than a top surface of the first insulating layer. A diffusion barrier layer is comprised between the via plugs and the interconnection landings. Each of the interconnection landings has a bottom surface of a rectangular shape, a square shape, a bar shape, a circular shape, or an elliptical shape. Each of the interconnection landings also has a larger bottom surface area than a top surface area of each of the via plugs. A lower conducting layer is below the first insulating layer and is connected to a bottom surface of the via plugs. The lower conducting layer can be a semiconductor substrate doped with impurity ions.

The embodiment of the inventive concept further includes a semiconductor device comprising a memory device portion and a logic device portion, the memory device portion of which includes a first insulating layer having a plurality of via plugs therein, a second insulating layer on the first insulating layer, and a conducting interconnection pattern disposed in the second insulating layer and having at least one interconnection landings arranged over and electrically connected to the via plugs.

The embodiment of the inventive concept further includes a method of fabricating a semiconductor device including forming a lower conducting layer, forming a first insulating layer on the lower conducting layer, forming a via plug vertically penetrating the first insulating layer and connected to the lower conducting layer, forming a second insulating layer on the first insulating layer and the via plugs, forming a first recess in the second insulating layer, the first recess having a bottom surface lower than a top surface of the second insulating layer, forming a trench in the second insulating layer and simultaneously further recessing the first recess to form a second recess; and forming a conducting material in the second recess and the trench.

In a preferred embodiment, the second recess has a bottom surface lower than a bottom surface of the trench in the interconnection insulating layer. The lower conducting layer is formed by implanting impurity ions into a semiconductor substrate. The first insulating layer is formed by depositing an insulating layer containing silicon oxide on the lower conducting layer. After forming the via plug, a top surface of the via plug and a top surface of the first insulating layer is planarized to have the same height. A capping layer is formed between the first insulating layer and the second insulating layer. The first recess is vertically aligned with the via plug. The second recess is formed to partially expose a top surface of the first insulating layer. After the second insulating layer is formed, a hard mask layer is formed on the second insulating layer, and the hard mask layer is patterned to form a hard mask pattern defining the trench and exposing the surface of the second insulating layer. A mask pattern is formed to define the first recess on the hard mask pattern, and the exposed second insulating layer is etched to form the first recess using the mask pattern as a patterning mask.

The embodiment of the inventive concept further includes an electronic system including a control unit, an input unit, an output unit, and a storage unit, wherein at least one of the control unit and the storage unit comprises a semiconductor device. The semiconductor device comprises first insulating layer having a plurality of via plugs therein, second insulating layer on the first insulating layer, and a conducting interconnection pattern disposed in the second insulating layer and having at least one interconnection landings arranged over and electrically connected to the via plugs.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1A is a schematic layout illustrating a semiconductor device according to an embodiment of the inventive concept;

FIG. 1B is sectional views taken along section lines I-I′ and II-II′ of FIG. 1A;

FIG. 2A is a schematic layout illustrating a semiconductor device according to another embodiment of the inventive concept;

FIG. 2B is sectional views taken along lines III-III′ and IV-IV′ of FIG. 2A;

FIG. 3A is a schematic layout illustrating a semiconductor device according to another embodiment of the inventive concept;

FIG. 3B is sectional views along lines V-V′, VI-VI′, and VII-VII′ of FIG. 3A;

FIG. 4A is a schematic layout illustrating a semiconductor device according to another embodiment of the inventive concept;

FIG. 4B is sectional views taken along lines VIII-VIII′, IX-IX′, and X-X′ of FIG. 4A;

FIGS. 5 through 12 are sectional views illustrating a method of fabricating semiconductor devices according to the embodiments of the inventive concept;

FIG. 13A is a schematic view of a semiconductor module including a semiconductor device according to embodiments of the inventive concept;

FIG. 13B is a block diagram of an electronic circuit board including a semiconductor device according to embodiments of the inventive concept; and

FIG. 13C is a block diagram of an electronic system including a semiconductor device or a semiconductor module having the semiconductor device according to embodiments of the inventive concept.

### DETAILED DESCRIPTION OF THE EMBODIMENTS

Embodiments according to the inventive concept will now be described more fully with reference to the accompanying drawings. These inventive concepts may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present inventive concept.

An “interconnection” may be understood a horizontally extending conductive element. For example, the “interconnection” may be understood geometric patterns having a vertical thickness, a horizontal width in first direction, and a horizontal length in second direction much greater than the vertical thickness and the horizontal width. A “via plug” may be understood a vertically extending element. For example, the “via plug” may be understood geometric patterns shaped pillars. A “landing” may be understood a pattern shaped a pad shape or a mesa shape. The “landing” may be understood a pattern having a horizontal width or diameter and a vertical height. The horizontal width or the diameter may be greater than the vertical height. Further, the “landing” may be understood a downwardly projecting element beneath a main element. Moreover, the “landing” may be understood a downwardly projecting part of a main element.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

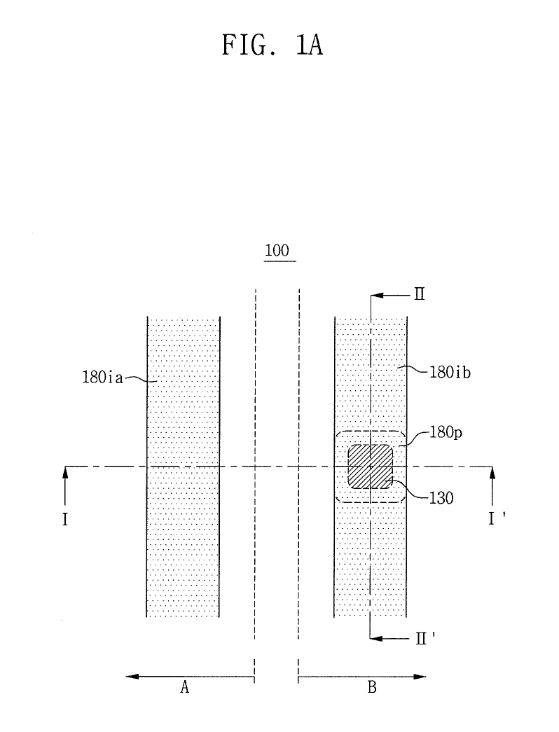

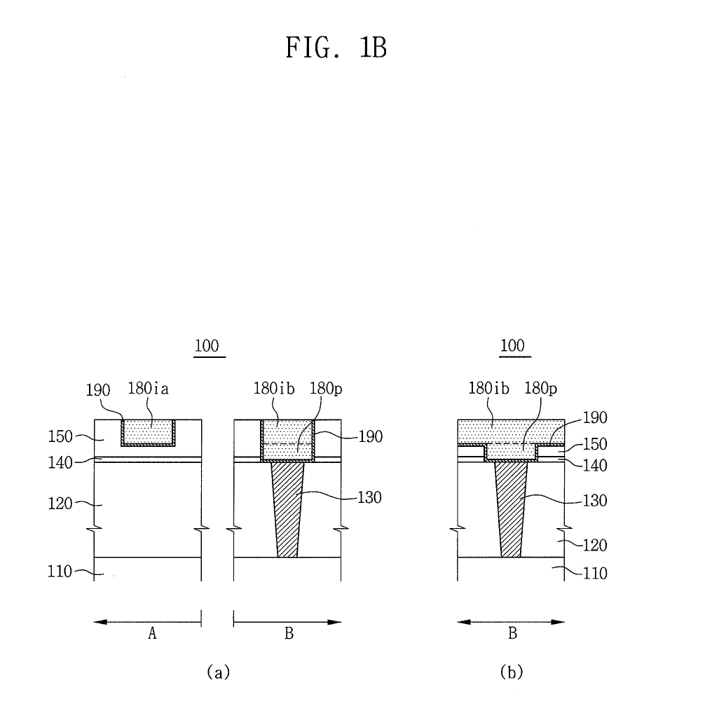

FIG. 1A is a schematic layout illustrating a semiconductor device according to an embodiment of the inventive concept, and the (a) and (b) of FIG. 1B are sectional views taken along section lines I-I′ and II-II′ of FIG. 1A, respectively.

Referring to FIGS. 1A and 1B, a semiconductor device 100 may include a lower layer 110 and an interlayer insulating layer 120 disposed on the lower layer 110. An interconnection insulating layer 150 may be disposed on the interlayer insulating layer 120. A via plug may be disposed vertically in the interlayer insulating layer 120, connecting to the lower layer 110. A first interconnection 180ia and a second interconnection 180ib may be disposed in the interconnection insulating layer 150. An interconnection landing 180p may be disposed between the second interconnection 180ib and the via plug 130. A capping layer 140 may be further disposed between the interlayer insulating layer 120 and the interconnection insulating layer 150. Alternatively, the capping layer 140 may not be disposed between the interlayer insulating layer 120 and the interconnection insulating layer 150.

The lower layer 110 may be a conductive material layer, for example, a semiconductor substrate or a conductive interconnection. The interlayer insulating layer 120 may be a material layer containing silicon oxide. The capping layer 140 may be a material layer having a denser material than the interlayer insulating layer 120 and having etch selectivity with respect to the interlayer insulating layer 120. The capping layer 140 may impede a flowability of the interlayer insulating layer 120. For example, the material layer may include a material containing silicon nitride.

The via plug 130 may be a material layer having a conductive material, such as a metal. The via plug 130 may transmit electric signals in a vertical direction.

The interconnection pattern, first and second interconnections 180ia and 180ib, may be configured to extend in a horizontal direction and transmit electric signals in the horizontal direction. The first and second interconnections 180ia and 180ib may be a patterned layer having a conductive material, for example, a metal.

The interconnection landing 180p may physically and/or electrically connect the via plug 130 to the second interconnection 180ib. The interconnection landing 180p may be vertically aligned with the via plug 130. The interconnection landing 180p may be directly formed beneath a bottom surface of the second interconnection 180ib. Alternatively, the interconnection landing 180p may be integrally formed with the second interconnection 180ib. As shown in FIG. 1A, the interconnection landing 180p may be formed in a square shape when view from a plan view. Alternatively, the interconnection landing 180p may be formed in a rectangular shape, a bar shape, a polygonal shape, a circular shape, or an elliptical shape when viewed from a plan view. The interconnection landing 180p may be formed to a greater cross-sectional area than the via plug 130.

A diffusion barrier layer 190 may be conformably formed between the via plug 130 and the interconnection landing 180p. The diffusion barrier layer 190 may also be conformably formed between the interconnection landing 180p and the interconnection insulating layer 150. Alternatively, the interconnection landing 180p and the second interconnection 180ib may be integrally formed of the same material. The via plug 130 may be formed of an element isolated from the interconnection landing 180p.

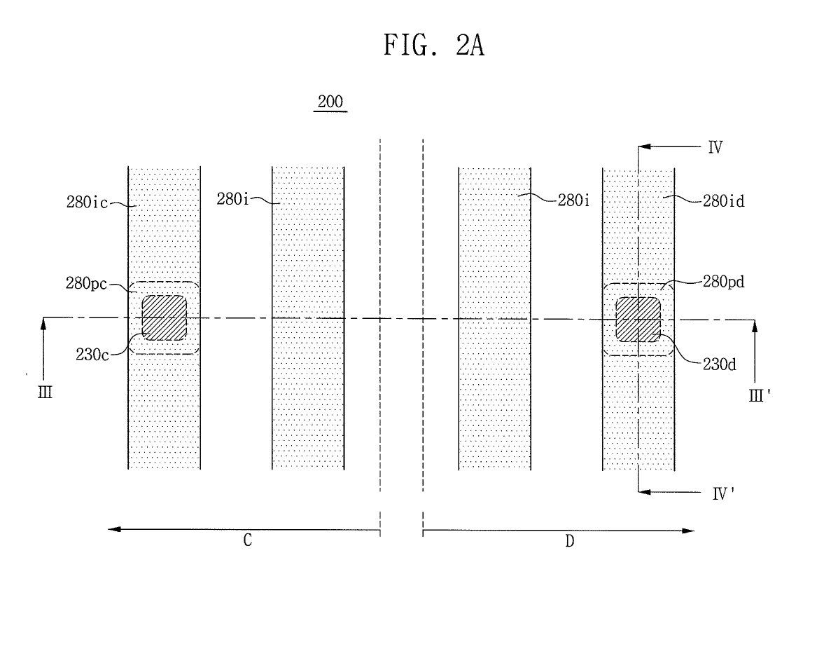

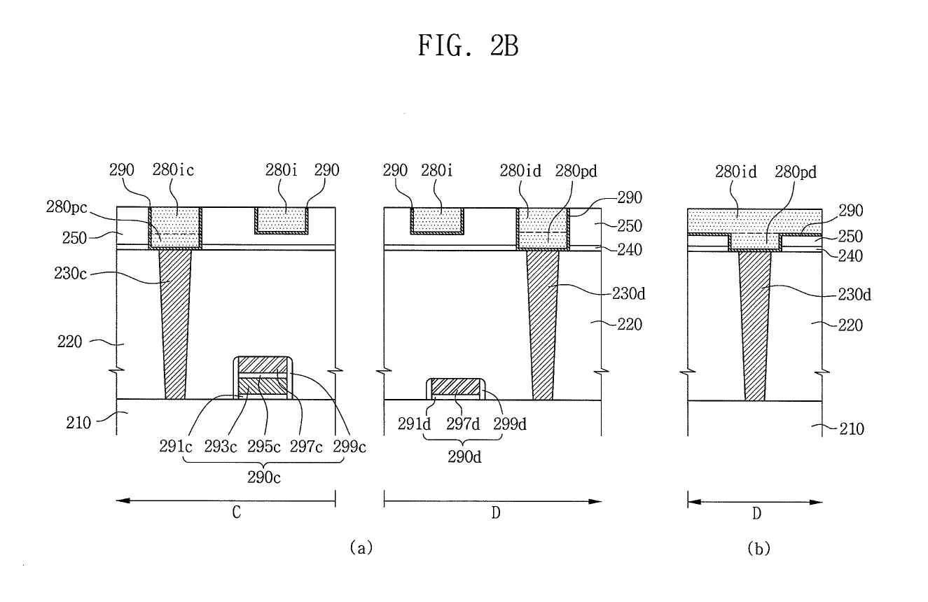

FIG. 2A is a schematic layout illustrating a semiconductor device according to another embodiment of the inventive concept, and The (a) and (b) of FIG. 2B are sectional views taken along section lines III-III′ and IV-IV′ of FIG. 2A, respectively.

Referring to FIGS. 2A and 2B, a semiconductor device 200 may include a first region C and a second region D. Each of the first and second regions C and D may include a lower layer 210 and an interlayer insulating layer 220 disposed on the lower layer 210. An interconnection insulating layer 250 may be disposed on the interlayer insulating layer 220. Via plugs 230c and 230d may vertically penetrate the interlayer insulating layer 220, connecting to the lower layer 210. Interconnections 280i, 280ic, and 280id may be disposed in the interconnection insulating layer 250. Interconnection landings 280pc and 280pd may be disposed between one of the interconnections 280ic and 280id and the via plug 230. A capping layer 240 may be further disposed between the interlayer insulating layer 220 and the interconnection insulating layer 250. Alternatively, the capping layer 240 may not be disposed between the interlayer insulating layer 220 and the interconnection insulating 250.

The first region C may include a higher element and the second region D may include a lower element. The first region C may include a first structure 290c formed to a greater height in the interlayer insulating layer 220, while the second region D may include a second structure 290d formed to a smaller height in the interlayer insulating layer 220. For example, a flash memory-logic embedded semiconductor chip in which a flash memory semiconductor chip and a logic semiconductor chip are integrated in a single chip, the first structure 290c may be a cell transistor formed in a flash memory semiconductor chip region. The first structure 290c may further include a string selection transistor and a ground selection transistor. The cell structure 290c may include a tunneling insulating layer 291c, a floating gate 293c, an inter-gate insulating layer 295c, a control gate 297c, and a spacer 299c. The second structure 290d may be a logic transistor formed in a logic semiconductor chip region. In this case, the logic transistor 290d may have a gate insulating layer 291d, a gate electrode 297d, and a spacer 299d. Alternatively, in the case of a DRAM memory-logic embedded semiconductor chip in which a DRAM memory device and a logic semiconductor device may be integrated in a single chip, the first structure 290c may be a word line, a storage via plug, or a cell capacitor formed in a cell region of a DRAM memory device. The second structure 290d may be a logic transistor formed in a logic semiconductor device region. Alternatively, the first and second structures 290c and 290d may be formed in the same memory device region having a cell region and peripheral region. For example, the first structure 290c may be formed in the cell region, while the second structure 290d may be formed in the peripheral region.

The lower layer 210 may be a material layer having a conductive material or conductive region, for example, a semiconductor substrate or a conductive interconnection. The interlayer insulating layer 220 may be formed of a material containing silicon oxide. The capping layer 240 may be a material layer having a denser material than the interlayer insulating layer 220 and having etch selectivity with respect to the interlayer insulating layer 220. The capping layer 240 may support the mobility of the interlayer insulating layer 220. For example, the capping layer 240 may be silicon nitride.

The via plugs 230c and 203d may be electrically and/or physically connected to the lower layer 210. The via plugs 230a and 230b may be formed of a conductive material, for example, a metal. The via plugs 230a and 230b may transmit electric signals in a vertical direction.

The interconnections 280i, 280ic, and 280id may be configured to extend in a horizontal direction and transmit electric signals in the horizontal direction. The interconnections 280i, 280ic, and 280id may be formed of a conductive material, for example, a metal.

The interconnection landings 280pc and 280pd may physically or electrically connect the via plugs 230c and 230d to the interconnections 280ic and 280id. The interconnection landings 280pc and 280pd may be vertically aligned with the via plugs 230c and 230d. That is, the interconnection landings 280pc and 280pd may be disposed only on the via plugs 230c and 230d. As shown in FIG. 2A, the interconnection landings 280pc and 280pd may have a larger contact area than the via plugs 230c and 230d.

A diffusion barrier layer 290 may be disposed between the via plugs 230c and 230d and the interconnection landings 280pc and 280pd. The diffusion barrier layer 290 may also be conformably disposed between the interconnection landings 280pc and 280pd and the interconnection insulating layer 250. The diffusion barrier layer 290 may also be conformably formed between the interconnections 280i, 280ic, and 280id and the interconnection insulating layer 250. Alternatively, the interconnection landings 280pc and 280pd may be integrally formed of the same material as the interconnections 280ic and 280id. The via plugs 230c and 230d may be formed of a component isolated from the interconnection landings 280pc and 280pd.

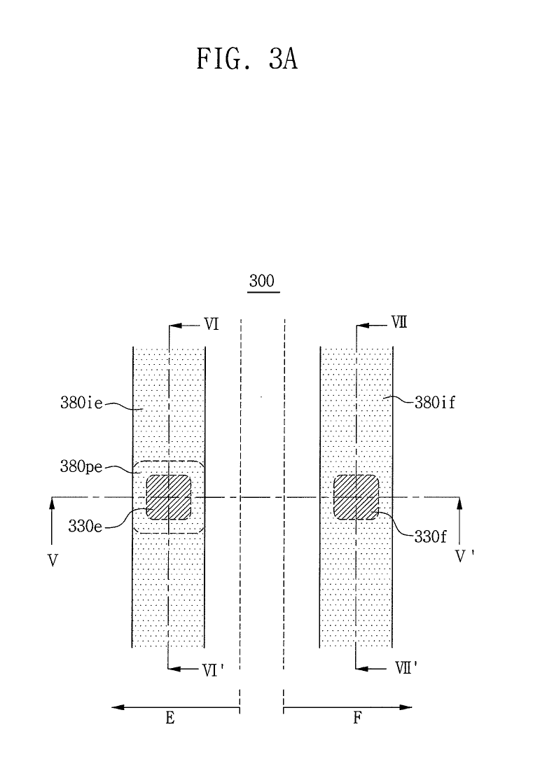

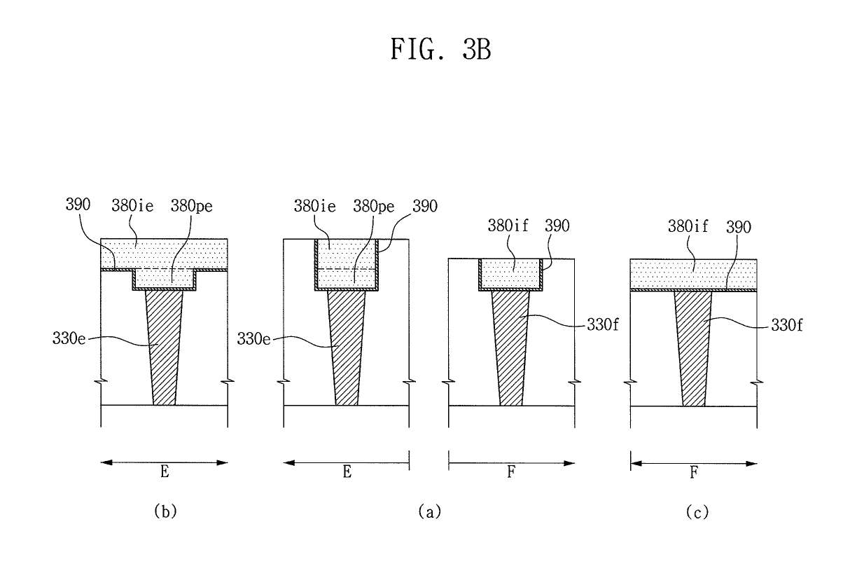

FIG. 3A is a schematic layout illustrating a semiconductor device according to another embodiment of the inventive concept, and the (b), (a), and (c) of FIG. 3B are sectional views taken along section lines V-V′, VI-VI′, and VII-VII′ of FIG. 3A, respectively.

Referring to FIGS. 3A and 3B, a semiconductor device 300 may include a first region E having an interconnection landing layer and a second region F having no interconnection landing layer. The first and second regions E and F may include a first via plug 330e and a second via plug 330f, respectively, which have the same height or be on the same level. Also, the first and second regions E and F may include a first interconnection 380ie and a second interconnection 380 if, respectively, which have different bottom surface heights or be formed on different bottom surfaces levels. Furthermore, the first region E may include an interconnection landing 380pe disposed between the first via plug 330e and the first interconnection 380ie. The interconnection landing 380pe may be integrally formed of the same material as the first interconnection 380ie. The first and second interconnections 380ie and 380if may have different surface heights or be on different surface levels. Other components of the semiconductor device 300 may be understood with reference to FIGS. 1A and 1B and descriptions thereof.

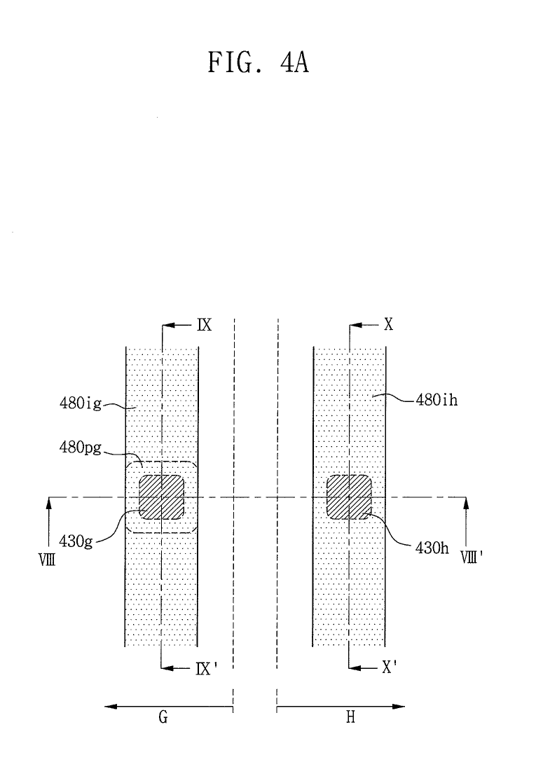

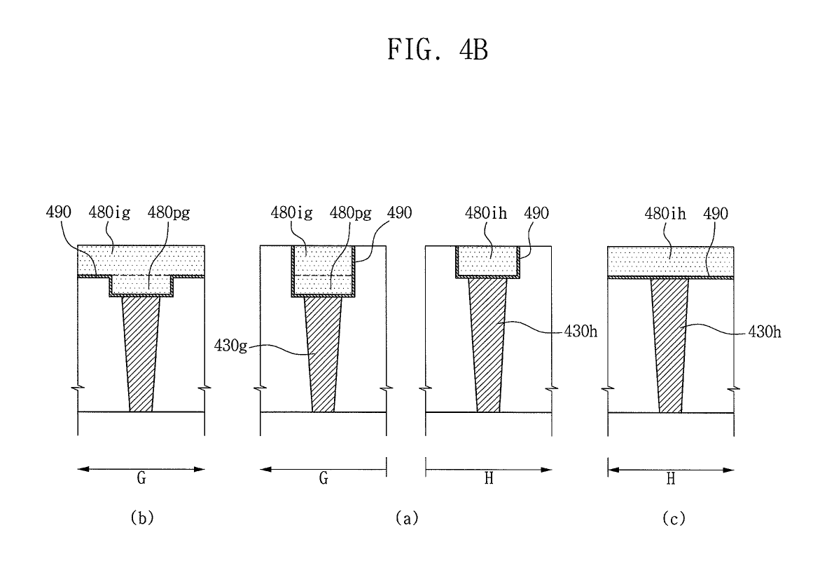

FIG. 4A is a schematic layout illustrating a semiconductor device according to another embodiment of the inventive concept, and the (b), (a), and (c) of FIG. 4B are sectional views taken along lines VIII-VIII′, IX-IX′, and X-X′ of FIG. 4A, respectively.

Referring to FIGS. 4A and 4B, a semiconductor device 400 may include a first region G having an interconnection landing layer 480pg and a second region H having no interconnection landing layer. The first and second regions G and H may include a first via plug 430g and a second via plug 430h, respectively, both of which have different heights or different top surface levels. The first and second regions G and H may include a first interconnection 480ig and a second interconnection 480ih, respectively, both of which have the same top surface height. The first region G may include an interconnection landing 480pg disposed between the first via plug 430g and the first interconnection 480ig. The first via plug 430g may have a lower height than the second via plug 430h. The first and second interconnections 480ig and 480ih may have the same height or levels at the top surface and/or the same height at the bottom surface. Other components of the semiconductor device 400 may be understood with reference to FIGS. 1A through 2B.

In the above-described embodiments, the shapes of the above structures implemented in real devices may be different from those shown in the drawings. The structures of real devices may be formed in different shapes according to the standards, degrees of alignment, and/or process conditions of respective components without departing from the spirit and scope of the inventive concept. This will be described in more detail in connection with a method of fabricating a semiconductor device according to embodiments of the inventive concept.

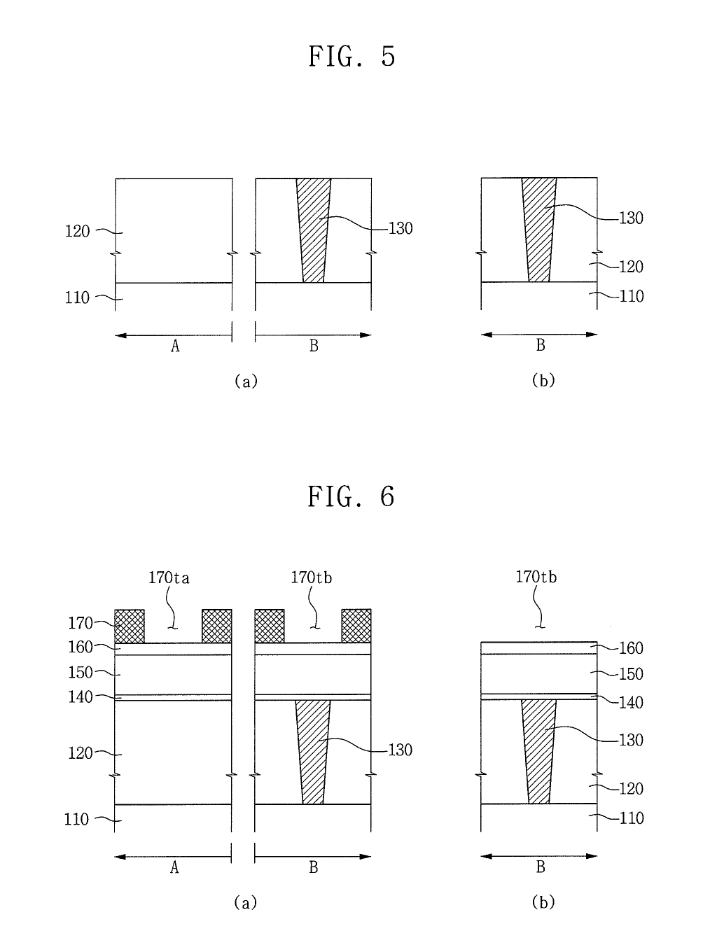

FIGS. 5 through 12 are sectional views illustrating a method of fabricating a semiconductor device according to an embodiment of the inventive concept. Specifically, the method of FIGS. 5 through 12 may be understood with reference to the two sectional views of FIG. 1B.

Referring to FIG. 5, an interlayer insulating layer 120 may be formed on a lower layer 110. A via plug 130 may be formed vertically in the interlayer insulating layer 120 and contact the lower layer 110. The lower layer 110 may be an impurity doped region in a semiconductor substrate, for example, a source or drain region. Alternatively, the lower layer 100 may be an interconnection layer, for example, a metal.

The interlayer insulating layer 120 may be a material layer including a silicate-based silicon oxide. For example, the silicate-based silicon oxide may include boron phosphor silicate glass (BPSG), boron silicate glass (BSG), phosphor silicate glass (PSG), undoped silicon glass USG, tetraethyl orthosilicate (TEOS), high-density plasma (HDP) oxide, or an insulating material containing other silicon oxides known to ordinary skilled person in the art. The interlayer insulating layer 120 may be formed using a chemical vapor deposition (CVD) process. Alternatively, the interlayer insulating layer 120 may be formed using a lower temperature coating process to reduce a thermal burden. For example, the different coating process may include a low-temperature-oxide (LTO) forming process at a temperature of about 400° C. or lower, or using a middle temperature oxide (MTO) forming process at a temperature of about 600° C. or lower. Alternatively, the interlayer insulating layer 120 may be formed using different processes. For example, a lower portion of the interlayer insulating layer 120 may be formed of a silicate insulating material, while an upper portion thereof may be formed of HDP oxide. Furthermore, the interlayer insulating layer 120 may be a stacked layer formed of variously insulating materials. The via plug 130 may be formed as a vertical pillar type in the interlayer insulating layer 120. The via plug 130 may be formed in a single or stacked layer structure of silicon (Si), silicide, a metal, or a metal compound. For example, the via plug 130 may be formed of conductive silicon, metal silicide, a metal compound, or a metal. The metal silicide may contain tungsten (W), cobalt (Co), nickel (Ni), copper (Cu), or other metals, and the metal compound may be tungsten nitride (WN) or titanium nitride (TiN). A diffusion barrier layer may be further formed at an interface between the via plug 130 and the lower layer 110 and/or an interface between the via plug 130 and the interlayer insulating layer 120. Although not shown, the diffusion barrier layer may be a stacked layer of a Ti layer and a TiN layer. The via plug 130 may form a planar top surface with the interlayer insulating layer 120 as a resultant structure through a planarization process, for example, a chemical mechanical polishing (CMP) process.

Referring to FIG. 6, a capping layer 140, an interconnection insulating layer 150, a hard mask layer 160, and a first mask pattern 170 may be sequentially formed on the planarized structure of interlayer insulating layer 120 and the via plug 130. The capping layer 140 may be a material layer having etch selectivity with respect to the interlayer insulating layer 120 and/or the interconnection insulating layer 150. For example, the capping layer 140 may be formed of a material containing silicon nitride (SiN), silicon carbide (SiC), or silicon carbon nitride (SiCN). The capping layer 140 may have a thickness smaller than the interlayer insulating layer 120 and the interconnection insulating layer 150 have. Alternatively, the capping layer 140 may not be formed when the interlayer insulating layer 120 has a stable characteristics or when a subsequent process of patterning the interconnection insulating layer 150 is stably performed. The interconnection insulating layer 150 may be a single or stacked layer including silicon oxide. The interconnection insulating layer 150 may have a thickness greater than the capping layer 140 has. The hard mask layer 160 may be formed of a material having etch selectivity with respect to the interconnection insulating layer 150. For example, the hard mask layer 160 may be formed of the same material as the capping layer 140. The hard mask layer 160 may be formed to facilitate a subsequent process of patterning the interconnection insulating layer 150. That is, when an additional patterning mask required for patterning the interconnection insulating layer 150 is formed, the hard mask layer 160 may not be required. The first mask pattern 170 may include a first mask trench 170ta and a second mask trench 170tb that partially expose the surface of the hard mask layer 160. The first and second mask trenches 170ta and 170tb may define positions where the interconnections 180ia and 180ib will be formed and/or shapes of the interconnections 180ia and 180ib. Each of the first and second mask trenches 170ta and 170tb may have a trench shape when viewed from a plan view. Here, the trench shape may refer to a 1-dimensional pattern shape, that is, a line shape. For example, the first mask pattern 170 may be a photo resist pattern.

Referring to FIG. 7, the exposed portions of the hard mask layer 160 by the first and second mask trenches 170ta and 170tb may be removed using the first patterning mask pattern 170 as a patterning mask, thereby forming a first hard mask trench 160ta and a second hard mask trench 160tb to expose the surface of the interconnection insulating layer 150. Thereafter, the first mask pattern 170 may be removed.

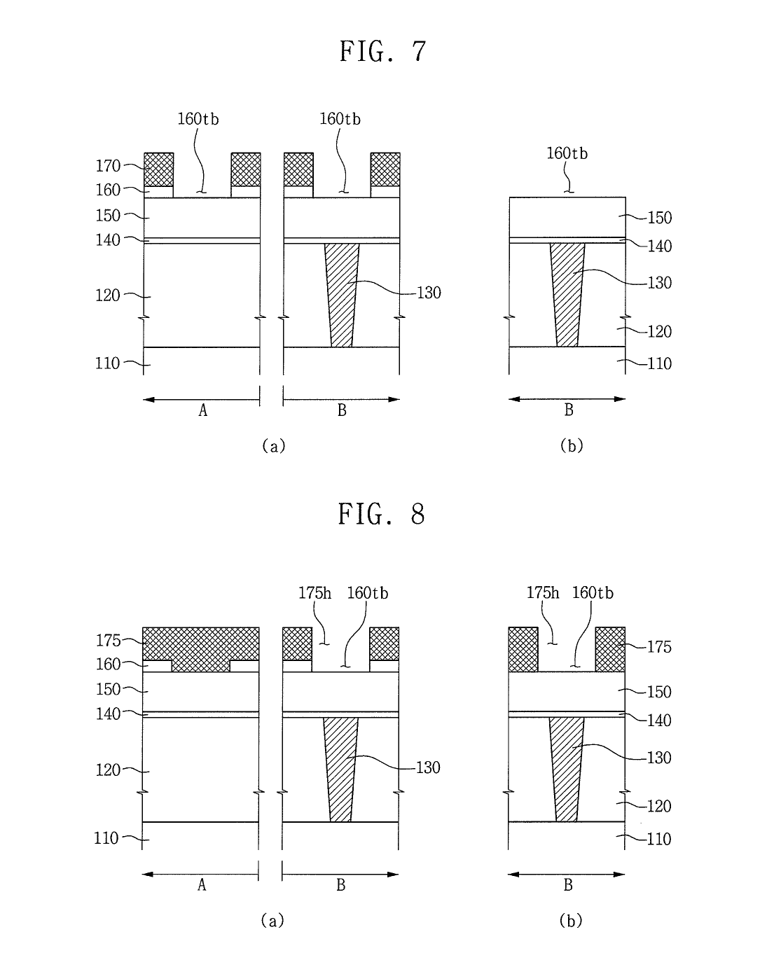

Referring to FIG. 8, a second mask pattern 175 may be formed on the hard mask layer 160 and the exposed interconnection insulating layer 150. The second mask pattern 175 may include a recess hole 175h aligned with a portion of the second hard mask trench 160tb. Also, the recess hole 175h may be vertically aligned with the via plug 130. The recess hole 175h may have a square shape. Alternatively, the recess hole 175h may have a rectangular shape, a bar shape, a polygonal shape, a circular shape, or an elliptical shape, when viewed from a plan view. Alternatively, the second mask pattern 175 may be a photoresist pattern.

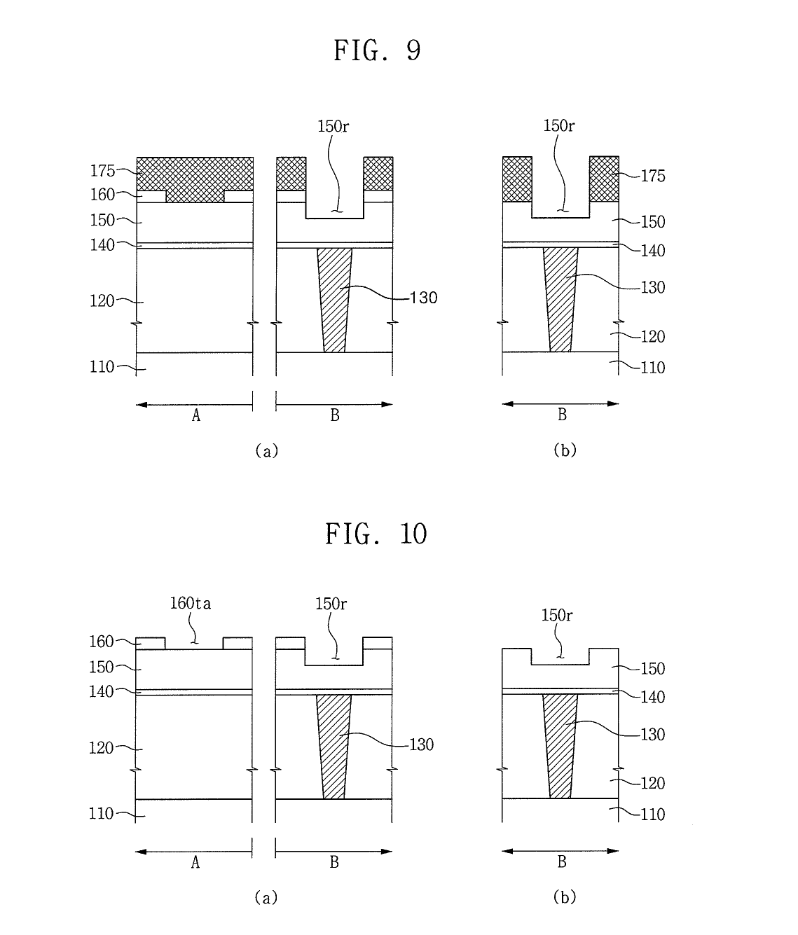

Referring to FIG. 9, the exposed interconnection insulating layer 150 by the recess hole 175h may be etched to form a recess 150r in the region B. The recess 150r may be formed by a partial etching process using the second mask pattern 175 as an etch mask. The partial etching process may be a time-controlled etching process where an etching process performs for a predetermined amount of time or to a predetermined depth in the interconnection insulating layer 150. This time-controlled etching process does not need an etch stop layer to prevent excessive over etch. The recess 150r may be formed in the same shape as the recess hole 175h when viewed from a plan view.

Referring to FIG. 10, the second mask pattern 175 may be removed. As a result, not only the hard mask layer 160 but also the first hard mask trench hole 160ta and the recess 150r, which expose the surface of the interconnection insulating layer 150, may be exposed.

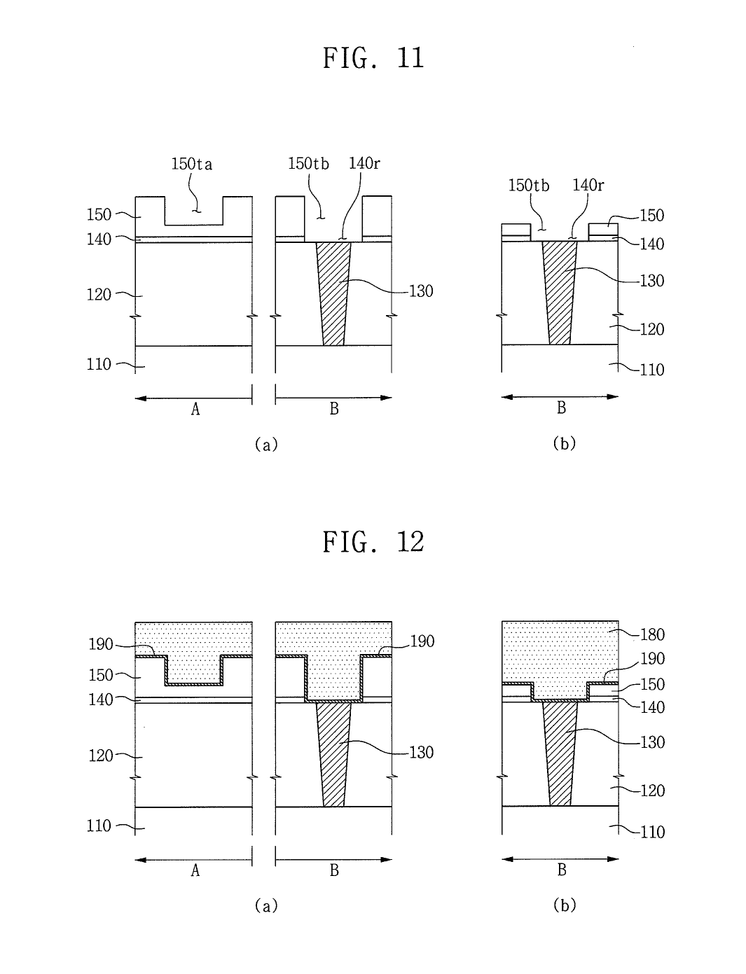

Referring to FIG. 11, the interconnection insulating layer 150 may be etched using the hard mask layer 160 as a patterning mask, thereby forming a first interconnection trench 150ta, a second interconnection trench 150tb, and an interconnection landing recess hole 140r. The hard mask layer 160 may be completely or mostly removed during the etching of the interconnection insulating layer 150. Alternatively, a large amount of the hard mask layer 160 may remain. The hard mask layer 160 may be completely removed. The capping layer beneath the interconnection landing recess hole 140r may be removed, so that the interlayer insulating layer 120 may be exposed as a resultant structure. Alternatively, the bottom surface of the interconnection landing recess hole 140r may be lower than the top surface of the via plug 130 because the etching process for forming the interconnection landing recess hole 140r may be excessively performed.

Referring to FIG. 12, a diffusion barrier layer 190 and a conductive interconnection material layer 180 may be formed on the interconnection insulating layer 150 including the first interconnection trench 150ta, the second interconnection trench 150tb, and the interconnection landing recess hole 140r sequentially. The diffusion barrier layer 190 may be the stacked layer of a Ti layer and a TiN layer. Alternatively, the diffusion barrier layer 190 may be the stacked layer of a tantalum (Ta) layer and a tantalum nitride (TaN) layer. The conductive interconnection material layer 180 may include, for example, copper (Cu), tungsten (W), aluminum (Al), titanium (Ti), tantalum (Ta), nickel (Ni), or other metals. The diffusion barrier layer 190 may be conformably formed on the resultant structure shown in FIG. 11. The conductive interconnection material layer 180 is formed on the diffusion barrier layer 190 using an electroplating deposition process wherein a metal seed layer is necessary to form the conductive interconnection material layer 180. A planarization process, for example, a CMP process, may be performed, thereby resulting in the structure of the semiconductor device 100 according to the embodiment of the inventive concept illustrated in FIGS. 1A and 1B. Methods of fabricating the semiconductor devices according to the various embodiments of the inventive concept as described with reference to FIGS. 2A through 4B may be fully understood and applied with reference to FIGS. 5 through 12 and the descriptions thereof.

Methods of fabricating semiconductor devices according to embodiments of the inventive concept have been described. It would be fully understood to one skilled in the art that the structures shown in FIGS. 1 through 5 may be embodied with reference to the above description.

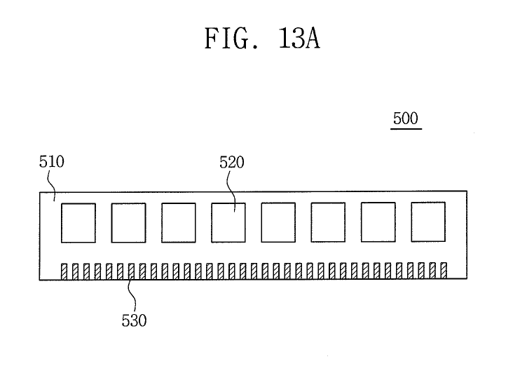

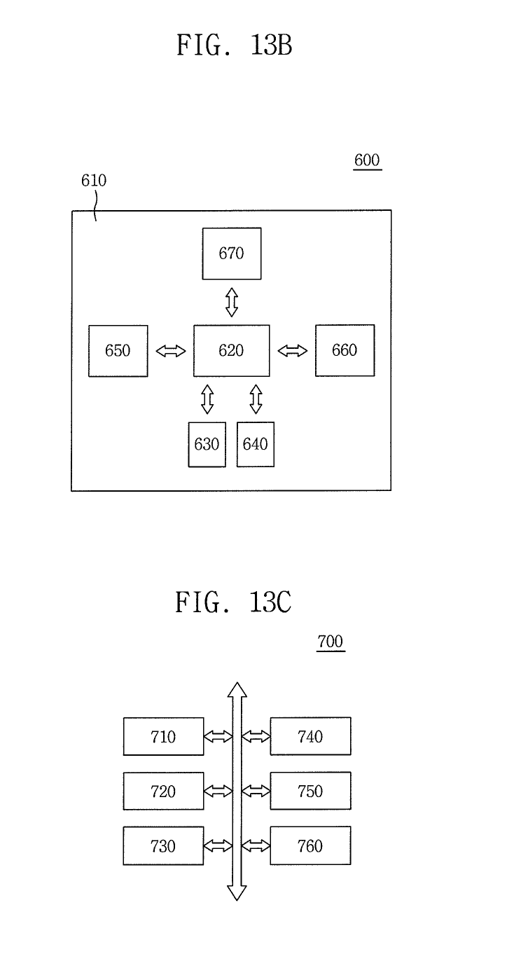

Hereinafter, a semiconductor module, an electronic circuit board, and an electronic system including a semiconductor device according to embodiments of the inventive concept will be described. FIG. 13A is a schematic view of a semiconductor module including a semiconductor device according to embodiments of the inventive concept. Referring to FIG. 13A, a semiconductor module 500 including a semiconductor device according to the embodiments of the inventive concept may include a module substrate 510 and a plurality of semiconductor devices 520 disposed on the module substrate 510. Module contact terminals 530 may be disposed on one edge of the module substrate 510 in a row and electrically connected to the semiconductor devices 520. The module substrate 510 may be a printed circuit board (PCB). Both surfaces of the module substrate 510 may be used so that the semiconductor devices 520 may be disposed on both front and rear surfaces of the module substrate 510. Although FIG. 13A illustrates 8 semiconductor devices 520 disposed on the front surface of the module substrate 510, the inventive concept is not limited thereto. The semiconductor module 500 may further include an additional semiconductor device configured to control the semiconductor devices 520. The semiconductor module 500 according to the present embodiments is not limited to the number and shape of the semiconductor devices 520 shown in FIG. 13A and may include semiconductor devices 520 of different number and shape than in FIG. 13A. At least one of the semiconductor devices 520 may include a structure of a semiconductor device according to the embodiments of the inventive concept. The module contact terminals 530 may be formed of a metal and have oxidation resistance. The number of the module contact terminals 530 may be different from as shown in FIG. 13A according to the standard of a semiconductor module.

FIG. 13B is a block diagram of an electronic circuit board including a semiconductor device according to the embodiments of the inventive concept. Referring to FIG. 13B, an electronic circuit board 600 may include a microprocessor (MP) 620, a main storage circuit 630, a supplementary storage circuit 640, an input signal processing circuit 650, an output signal processing circuit 660 and a communication signal processing circuit 670, which are disposed on a circuit board 610. The main storage circuit 630 and the supplementary storage circuit 640 may communicate with the MP 620. The input signal processing circuit 650 may transmit commands to the MP 620. The output signal processing circuit 660 may receive commands from the MP 620. The communication signal processing circuit 670 may exchange electrical signals with other circuit boards. Arrows may be interpreted as signal paths through which the electric signals may be transmitted. The MP 620 may receive and process various electric signals, output processing results, and control other components of the circuit board 610. The MP 620 may be interpreted as, for example, a central processing unit (CPU) and/or a main control unit (MCU). The main storage circuit 630 may temporarily store data always or frequently required by the MP 620 or pre- and post-processing data. Since the main storage circuit 630 requires high response speed, the main storage circuit 630 may include a semiconductor memory device. More specifically, the main storage circuit 630 may be a cache semiconductor memory or include a static random access memory (SRAM), a dynamic RAM (DRAM), a resistive RAM (RRAM), and applied semiconductor memories thereof, such as a utilized RAM, a ferroelectric RAM (FRAM), a fast-cycle RAM, a phase-changeable RAM (PRAM), a magnetic RAM (MRAM), and other semiconductor memories. In addition, the main storage circuit 630 may include a volatile or non-volatile random access memory device. In the present embodiments, the main storage circuit 630 may include at least one semiconductor device according to embodiments of the inventive concept or at least one semiconductor module 500 including the semiconductor device. The supplementary storage circuit 640 may be a mass storage device, which is a nonvolatile semiconductor memory such as a flash memory device, a hard disk drive (HDD) using a magnetic field, or a compact disk drive (CDD) using light. The supplementary storage circuit 640 may be used to store a large amount of data even at low processing speed as compared with the main storage circuit 630. The supplementary storage circuit 640 may include a random or non-random nonvolatile memory device. The supplementary storage circuit 640 may include at least one semiconductor device according to embodiments of the inventive concept or at least one semiconductor module 500 including the semiconductor device. The input signal processing circuit 650 may convert an external command into an electrical signal or transmit an external electric signal to the MP 620. The external command or electric signal may be an operation command, an electrical signal to be processed, or data to be stored. The input signal processing circuit 650 may be, for example, a terminal signal processing circuit, an image signal processing circuit, one of various sensors, or an input signal interface. The terminal signal processing circuit may be configured to process a signal transmitted from a keyboard, a mouse, a touch pad, an image recognizer, or various sensors, and the image signal processing circuit may be configured to process image signals transmitted from a scanner or a camera. The input signal processing circuit 650 may include at least one semiconductor device according to embodiments of the inventive concept or at least one semiconductor module including the semiconductor device. The output signal processing circuit 660 may be a component configured to externally transmit the electric signal processed by the MP 620. For example, the output signal processing circuit 660 may be a graphics card, an image processor, an optical converter, a beam panel card, or a multifunctional interface circuit. The output signal processing circuit 660 may include at least one semiconductor device according to embodiments of the inventive concept or at least one semiconductor module 500 including the semiconductor device. The communication signal processing circuit 670 may be a component configured to directly exchange electric signals with another electronic system or circuit board without passing through the input signal processing circuit 650 or the output signal processing circuit 660. For example, the communication signal processing circuit 670 may be a modem of a personal computer (PC) system, a local area network (LAN) card, or one of various interface circuits. The communication signal processing circuit 670 may include at least one semiconductor device according to embodiments of the inventive concept or at least one semiconductor module 500 including the semiconductor device.

FIG. 13C is a schematic block diagram of an electronic system including a semiconductor device or semiconductor module having the semiconductor device according to embodiments of the inventive concept.

Referring to FIG. 13C, an electronic system 700 according to embodiments of the inventive concept may include a control unit 710, an input unit 720, an output unit 730, and a storage unit 740. The electronic system 700 may further include a communication unit 750 and/or an operation unit 760. The control unit 710 may control all of the electronic system 700 and respective components at one time. The control unit 710 may be interpreted as a CPU or MCU. The control unit 710 may include the electronic circuit board 600 according to the embodiments of the inventive concept. The control unit 710 may further include at least one semiconductor device according to embodiments of the inventive concept or at least one semiconductor module 500 including the semiconductor device. The input unit 720 may transmit an electric command signal to the control unit 710. The input unit 720 may be an image recognizer, such as a keyboard, a keypad, a mouse, a touch pad, or a scanner, or one of various input sensors. The input unit 720 may include at least one semiconductor device according to embodiments of the inventive concept or at least one semiconductor module 500 including the semiconductor device. The output unit 730 may receive an electrical command signal from the controller 710 and output a processing result of the electronic system 700. The output unit 730 may be a monitor, a printer, a beam emitter, or one of various mechanical apparatuses. The output unit 730 may include at least one semiconductor device according to the embodiments of the inventive concept or at least one semiconductor module 500 including the semiconductor device. The storage unit 740 may be a component configured to temporarily or permanently store signals to be processed or already processed by the control unit 710. The storage unit 740 may be physically and electrically connected or combined with the control unit 710. The storage unit 740 may be a semiconductor memory device, a magnetic storage device such as a hard disk, an optical storage device such as a compact disk, or a server having another data storage function. The storage unit 740 may include at least one semiconductor device according to embodiments of the inventive concept or at least one semiconductor module 500 including the semiconductor device. The communication unit 750 may receive an electric command signal from the control unit 710 and transmit or receive the electric signal to or from another electronic system. The communication unit 750 may be a wired transceiver device such as a modem or a LAN card, a wireless transceiver device such as a wireless broadband (WiBro) interface, or an infrared (IR) port. The communication unit 750 may include at least one semiconductor device according to the embodiments of the inventive concept or at least one semiconductor module 500 including the semiconductor device. The operation unit 760 may be capable of physical or mechanical operations in response to commands of the control unit 710. For example, the operation unit 760 may be a component capable of mechanical operations, such as a floater, an indicator, or an up/down operator. The electronic system 700 according to embodiments of the inventive concept may be a computer, a network server, a networking printer, a scanner, a wireless controller, a mobile communication terminal, an exchange, or one of other electronic devices capable of programmed operations.

The names and functions of components that are not explained may be easily understood with reference to other drawings of the present specification and descriptions thereof.

In a semiconductor device according to the embodiments of the inventive concept, even if there are differences in height between respective regions and/or components, a via plug and an interconnection can be stably physically and/or electrically connected to each other. As a result, manufacturing yield can be increased, fabrication cost can be reduced, and the performance of semiconductor devices can be improved.

The foregoing is illustrative of embodiments and is not to be construed as limiting thereof. Those skilled in the art will readily appreciate that many modifications are possible in the embodiments of the inventive concept without materially departing from the novel teachings and advantages. Accordingly, all such modifications are intended to be included within the scope of this inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A semiconductor device, comprising:
a first insulating layer having a plurality of via plugs therein;
a second insulating layer on the first insulating layer; and
a conducting interconnection pattern disposed in the second insulating layer and having at least one interconnection landing arranged over and electrically connected to the via plugs.

2. The semiconductor device of claim 1, wherein a portion of the conducting interconnection pattern other than the interconnection landings has a bottom surface higher than a top surface of the first insulating layer.

3. The semiconductor device of claim 1, further comprising a diffusion barrier layer between the via plugs and the interconnection landings.

4. The semiconductor device of claim 1, wherein each of the interconnection landings has a bottom surface of a rectangular shape, a square shape, a bar shape, a circular shape, or an elliptical shape.

5. The semiconductor device of claim 1, wherein each of the interconnection landings has a larger bottom surface area than a top surface area of each of the via plugs.

6. The semiconductor device of claim 1, further comprising a lower conducting layer below the first insulating layer and connected to a bottom surface of the via plugs.

7. The semiconductor device of claim 6, wherein the lower conducting layer is a semiconductor substrate doped with impurity ions.

8. A semiconductor device, comprising:
a memory device portion; and
a logic device portion,
wherein the memory device portion includes:
a first insulating layer having a plurality of via plugs therein;
a second insulating layer on the first insulating layer; and
a conducting interconnection pattern disposed in the second insulating layer and having at least one interconnection landings arranged over and electrically connected to the via plugs.

9. The semiconductor device of claim 1, wherein the bottom surface of the conducting interconnection pattern is higher than the top surface of the first insulating layer.

10. The semiconductor device of claim 1, further comprising a diffusion barrier layer between the via plugs and the interconnection landings.

11-20. (canceled)
